(19) United States
(12) Patent Application Publication
(10) Pub. No.: US 2012/0322008 A1
(43) Pub. Date: Dec. 20, 2012

(54) DEVELOPMENT OF PRINTING MEMBERS HAVING POST-ANODICALLY TREATED SUBSTRATES

(76) Inventors: Kevin Ray, Windham, NH (US); Frederick Richard Kearney, Walpole, MA (US); David B. Baker, Hudson, NH (US)

(21) Appl. No.: 13/161,807

(22) Filed: Jun. 16, 2011

(51) Int. Cl. G03F 7/20

(52) U.S. Cl. 430/300

(57) ABSTRACT

Gum solutions are formulated to protect a negative-working photopolymer imaging layer coated on an anodized aluminum substrate that has undergone a post-anodic sealing treatment with inorganic phosphate and inorganic fluoride, followed by development. In various embodiments, the developer and gum solution have different compositions but contain at least one polycarboxylic acid—which may be a polymer—that beneficially desensitizes the surface after the unexposed photopolymer layer is removed.

### BACKGROUND OF THE INVENTION

In offset lithography, a printable image is present on a printing member as a pattern of ink-accepting (oleophilic) and ink-rejecting (oleophobic) surface areas. Once applied to these areas, ink can be efficiently transferred to a recording medium in the imagewise pattern with substantial fidelity. Dry printing systems utilize printing members whose ink-repellent portions are sufficiently phobic to ink as to permit its direct application. In a wet lithographic system, the non-image areas are hydrophilic, and the necessary ink-repellency is provided by an initial application of a dampening fluid or “fountain solution” to the plate prior to inking The dampening fluid prevents ink from adhering to the non-image areas, but does not affect the oleophilic character of the image areas. Ink applied uniformly to the printing member is transferred to the recording medium only in the imagewise pattern. Typically, the printing member first makes contact with a compliant intermediate surface called a blanket cylinder which, in turn, applies the image to the paper or other recording medium. In typical sheet-fed press systems, the recording medium is pinned to an impression cylinder, which brings it into contact with the blanket cylinder.

Traditional negative-working photopolymer plates include a hydrophilic (typically grained metal) substrate and, thereover, a polymerizable coating. When exposed to actinic radiation the coating crosslinks, hardening and substantially increasing its adhesion to the underlying substrate. Following exposure of the plate to actinic radiation in an imagewise pattern (e.g., by a light source directed through a patterned mask or by laser that scans the plate and is selectively activated in accordance with the image pattern), the plate is subjected to the action of a developer, which removes unexposed portions of the photopolymer coating. These plates are “negative-working” or “direct-write” in the sense that inherently ink-receptive areas receive laser output and persist through development, which reveals the underlying hydrophilic substrate in “background” areas that will reject ink.

Aluminum has been used for many years as a support for lithographic printing plates. In order to prepare the aluminum for such use, it is typically subject to both a graining process and a subsequent anodizing process. The graining process serves to improve the adhesion of the image areas to the plate and to enhance the water-receptive characteristics of the background plate regions. Both mechanical and electrolytic graining processes are well known and widely used in the manufacture of lithographic printing plates. Anodizing creates an anodic oxide coating, which renders the surface hydrophilic and mechanically durable. In order to provide sufficient hydrophilicity for lithographic printing applications, the anodized layer of an aluminum substrate is frequently subjected to any of several post-anodic sealing treatments. The simplest treatment is subjection to hot water. More common post-anodic surface treatments utilize chemicals to further promote hydrophilicity. These chemicals include sodium silicate, a combination of inorganic phosphate and fluoride salts (usually a monosodium phosphate solution containing sodium fluoride), and treatment with organic polymeric acid (most commonly polymeric phosphonic acids as are well known in the art).

Promotion of hydrophilicity, however, is only one consideration in choosing a surface treatment for the substrate. The crosslinked photopolymer must also have sufficient adhesion in a commercial printing environment to provide adequate plate durability. If the surface of the substrate is too hydrophilic, or does not exhibit sufficient adhesion to the imaging layer after development, the interfacial bond between the ink-receiving layer and the substrate can be weakened by the fountain solution, leading to reduced durability. This problem can be exacerbated by the use of alcohol substitutes, as is prevalent in the United States. Promoting the hydrophilicity of non-image plate regions for printing purposes, therefore, can come at the expense of ink-transfer performance and overall plate durability. Moreover, not all surface treatments provide sufficient hydrophilicity by themselves. Some treatments, such as those utilizing sodium silicate or poly(vinyl phosphonic acid), can provide a sufficiently hydrophilic surface whereas others, such as a phosphate-fluoride treatment, produce a surface that promotes strong adhesion (and consequent plate durability) but are insufficiently hydrophilic in the presence of certain inks and fountain solutions, necessitating chemical treatment in the development stage to prevent the surface from accepting ink. In addition, while phosphate-fluoride treatment provides highly durable surfaces, these come at the price of resistance to development, resulting in the need for aggressive developer chemistries.

Developers for negative-working plates are generally alkaline, typically ranging in pH from 9 to 11. The alkalinity of negative developers is produced by any of several bases, such as sodium silicate or sodium hydroxide, and occasionally by the use of water soluble amines; it may be stabilized by the use of buffers, including phosphates, carbonates, and salts of organic acids. Developers may also contain surfactants to assist in the removal of the non-imaged coating and prevent it from being redeposited on the hydrophilic surface exposed by development. Cosolvents, such as benzyl alcohol or phenoxyethanol, may also be used. However, the pH and solvent content of these developers can make the mixture a hazardous material, which requires special handling and shipping, and expensive waste disposal once the developer is spent. Accordingly, more aggressive developer chemistries come at the price of handling and disposal difficulties and potential environmental toxicity.

### SUMMARY OF THE INVENTION

The present invention is directed toward obtaining the durability benefits of phosphate-fluoride surface treatments while mitigating its disadvantages, i.e., lack of adequate hydrophilicity and the need for developers that may be hazardous. Developer compositions in accordance herewith offer the safety, economic, and ecological benefits of a non-hazardous developer solution.

Particularly where long-term plate storage is required prior to use on-press, a gum solution is applied to the plate following development. As known in the art, a finisher gum solution is an aqueous liquid that comprises one or more surface-protective compounds capable of protecting the lithographic image of the printing plate against contamination or damage (for example, oxidation, fingerprints, dust or scratches). There are two types of “gum” solutions in common use: (1) a “bake,” “baking,” or “pre-bake” gum usually contains one or more compounds (e.g., one or more anionic surfactants) that do not evaporate at the usual pre-bake temperatures used for making lithographic printing plates; and (2) a “finisher” gum that usually contains one or more hydrophilic polymers (synthetic and/or naturally-occurring, such as gum Arabic cellulosic compounds, (meth)acrylic acid polymers, and polysaccharides) that are useful for providing a protective overcoat on a printing plate.

Accordingly, in a first aspect, the invention pertains to a method of developing a printing member having a negative-working photopolymer imaging layer on an anodized aluminum substrate, in particular a substrate that has been subjected to (i) a post-anodic sealing treatment of the substrate comprising exposure to an inorganic phosphate and an inorganic fluoride, and (ii) imagewise exposure of the printing member to actinic imaging radiation. The method comprises the step of removing unimaged portions of the photopolymer by applying to the printing member a developer composition comprising water, a surfactant, and a polycarboxylic acid; and protecting the printing member by applying thereto a finisher gum solution having a composition different from the developer composition.

In various embodiments, the developer composition has a pH in the range of 7 to 8.5 and the finisher gum solution has a pH in the range of 2 to 8.5, especially 3 to 5.5. The finisher gum solution may comprise or consist essentially of water, surfactant and a polycarboxylic acid. It may also include a hydrophilic polymer. The polycarboxylic acid may be citric acid, and may constitute from 0.05 to 1% of the developer composition and from 0.02 to 1% of the finisher gum solution. (All percentages given herein are weight percentages unless otherwise indicated.)

In various embodiments, the surfactant is an anionic surfactant, e.g., a salt of an aryl sulfonic acid. The anionic surfactant may be present at a level ranging from 2.5% to 7.5% by volume. The composition may, in various embodiments, also include a defoaming agent. In some embodiments, the developer composition further comprises an organic, water-miscible cosolvent which may, for example, be present at a level no greater than 5%. The cosolvent may, for example, be one or more of benzyl alcohol, phenoxyethanol and/or propylene carbonate.

The developer composition and the finisher gum solution may be applied to the printing member using a mechanical processor. The developer composition is typically applied to the printing member through at least one spray bar and the printing member is then rubbed with at least one rotary brush. The printing member may subsequently pass through a squeeze roller before the finisher gum solution is applied as a thin layer onto the member, which is then allowed to dry in place. The thin layer of finisher gum solution may have a dry deposited weight ranging from 0.1 to 0.5 g/m², especially 0.15 to 0.3 g/m². An optional rinse stage may occur after rubbing the printing member with a rotary brush and before finisher gum solution is applied.

It should be stressed that, as used herein, the term “plate” or “member” refers to any type of printing member or surface capable of recording an image defined by regions exhibiting differential affinities for ink and/or fountain solution. Suitable configurations include the traditional planar or curved lithographic plates that are mounted on the plate cylinder of a printing press, but can also include seamless cylinders (e.g., the roll surface of a plate cylinder), an endless belt, or other arrangement. The term “substantially” means ±10% (e.g., by weight or by volume), and in some embodiments, ±5%. The term “consists essentially of” means excluding other materials that contribute to function. For example, a composition having a surfactant that consists essentially of a salt of an aryl sulfonic acid contains no other material functioning as a surfactant, although it may contain ingredients that do not contribute to this function.

### DETAILED DESCRIPTION

In various embodiments, developer compositions in accordance with the present invention are formulated to develop a negative-working photopolymer imaging layer coated on an anodized aluminum substrate that has undergone a post-anodic sealing treatment with inorganic phosphate and inorganic fluoride (usually a monosodium phosphate solution containing sodium fluoride), hereafter “PF.” The developer composition contains at least one polycarboxylic acid—which may be a polymer—that beneficially (and surprisingly) desensitizes the surface after the unexposed photopolymer layer is removed. The polycarboxylic acid is typically present in amounts sufficient to adjust pH, but in greater than trace amounts: typical levels are between 0.05 and 1%, more preferably between 0.05 and 0.2%. A post-development finisher gum solution may also contain a polycarboxylic acid in amounts ranging from 0.02 to 1%.

Typically the developer composition has a pH in the range of 7 to 8.5 and the finisher gum solution has a pH in the range of 2 to 8.5, especially 3 to 5.5. Like the developer composition, the finisher gum solution may comprise or consist essentially of water, surfactant and a polycarboxylic acid. It may also include a hydrophilic polymer.

Following development, the applied finisher gum solution may be dried in place to produce a protective layer. The deposited weight of the finisher gum solution after drying is typically between 0.1 g/m² and 0.5 g/m², and preferably from 0.15 to 0.3 g/m². Achieving and retaining the desired pH of the finisher gum solution may necessitate the use of buffering salts and acids. The finisher gum solution may also desensitize the hydrophilic surface against ink receptivity. Various other functional additives, such as defoamers, sequestrants, and biocides may be added to the developer composition and/or to the finisher gum solution to improve or ensure performance and longevity in the commercial pressroom.

The finisher gum solution and/or developer composition may contain a surfactant to assist in the removal of unexposed areas of the photopolymer. The surfactant is typically an anionic surfactant, and more preferably a salt of an aryl sulfonic acid. Useful aryl sulfonic acids salts include alkylbenzenesulfonic acid salts, alkylnapthalenesulfonic acid salts, alkyphenoxypolyoxyethylenesulfonic acid salts, alkyldiphenylene oxide disulfonic acid salts, and other salts of chemically similar composition. Alkylnaphthalene sulfonic acid salts or alkyldiphenylene oxide disulfonic acid salts offer effectiveness as developers and affordable cost. The anionic surfactant is typically used at 2.5 to 7.5%, and preferably at 4 to 6%.

Water-miscible cosolvents known in the art may be used at levels sufficient for promoting removal of unexposed photopolymer, but may be limited to use levels that are acceptable for municipal wastewater streams and which avoid classification of the developer or gum as a hazardous material. In various embodiments, cosolvent levels are less than 5% of the total formulation, but may desirably be less than 1.5%, and more preferably less than 1%. Typical compounds used as cosolvents include benzyl alcohol, phenoxyethanol, glycol ethers such as ethylene glycol butyl ether, n-methyl pyrollidone, and derivatives thereof

Since surfactants used in the formulations described herein have a tendency to promote the production of foam, which can be disruptive when used in a commercial plate processor, a defoaming agent is typically used in the formulation at levels recommended by the manufacturer (typically less than 0.1%). A number of commercially available defoamers can be advantageously used. Other commercially available functional additives, such as biocides, sequestrants, and dyes, may also be included at levels recommended by their manufacturers, and these use levels are also typically on the order of 0.1% or less.

The pH of the developer composition may be stabilized by a buffer comprising a combination of acidic and basic salts. A number of materials can be used to buffer the pH within the range of 7 to 8.5. A pH of 7 or lower fails to provide sufficient development of the unimaged photopolymer coating, while a pH of 8.5 or more may cause the developer composition to be classified as a hazardous material. Various materials can be used to provide a pH in the desired range, including phosphate salts, carboxylic acid salts, carbonates, and the like. However, it has surprisingly been found that the use of polycarboxylic acids, such as citric acid, is critical for the developer composition to produce a hydrophilic surface that does not attract ink in the presence of fountain solution. The combination of a PF sealing treatment for optimal adhesion with the use of polycarboxylic acids to provide a sufficiently ink-rejecting hydrophilic surface on the developed substrate is highly advantageous.

Furthermore, it has also surprisingly been discovered that the pH of the developer composition can limit the ability of the developed surface to reject ink. Developer compositions with a pH of 9.2 or less are capable of producing a cleaned surface that is not ink-receptive in the presence of a fountain solution, yet developer compositionss with a pH of 11.35 or greater produce an ink-receptive developed surface. To keep the composition non-hazardous, the preferred pH range is 7 to 8.5.

Developer compositions and finisher gum solutions in accordance herewith can be formulated and mixed in any of various ways. The polycarboxyic acids may be added as a dry powder or a pre-made stock solution, depending on which approach is most expedient or cost effective. Similar considerations may determine the manner of mixing other components of the formulation, such as companion salts for the pH buffer, defoamers, cosolvents, surfactants, and other additives. In general, water is the primary solvent used in the developer compositions and finisher gum solutions. These compositions can be mixed by use of an overhead mechanical stirrer with a stir blade, with the components being added in a desired order as long as the amount of water present in the mixture is sufficient to dissolve the component; in general, however, it is convenient to dissolve the buffer salts first, and then the remaining components.

The developer composition may be applied to the plate surface by hand, but is more typically used in a mechanical processor with at least one tank dedicated to the developer composition and rotary brushes to mechanically scrub and remove non-imaged portions of the exposed plates. Typically, at least one spray bar applies developer fluid, which is recirculated into a reservoir; alternatively, the plate can be immersed in the reservoir. The processor may contain at least one set of rotating scrub brushes that scrub the plate surfaces in the presence of the developer composition, and preferably at least two sets of rotating brushes. An optional rinse stage may be included after the developer stage. The “gumming stage” follows the developer and optional rinse stages; in a typical implementation, the finisher gum solution is sprayed onto the plate surface after development and a squeeze roller is used to meter a thin layer of the finisher gum solution onto the plate, which is then allowed to dry in place.

More generally, the finisher gum solution may be applied to the printing member by rubbing, spraying, jetting, dipping, coating, or wiping the outer region with the finisher gum solution or a roller, impregnated pad, or applicator containing the finisher gum solution. For example, the printing member can be brushed with the finisher gum solution, or the finisher gum solution may be poured on or applied by spraying the member with sufficient force to remove the unwanted regions using a spray nozzle system. Still again, the printing member can be immersed in the finisher gum solution and rubbed by hand or with an apparatus.

Following gumming, the resulting lithographic printing member can be used for printing. However, before printing, any excess gum solution may be removed from the lithographic printing member by wiping or use of a squeegee or a pair of nip rollers in an apparatus, followed by optional drying using any suitable drying means.

A post-bake operation can be carried out on the printing member, with or without a blanket or flood-wise exposure to ultraviolet (UV) or visible radiation. Alternatively, a blanket UV or visible radiation exposure can be carried out, without a post-bake operation.

Once the plate has been fully processed, it can be mounted on an offset printing press and used to print several thousand sheets using conventional printing inks and fountain solutions, e.g., up to 100,000 impressions. If the developer composition is used with a plate that has received a post-anodic treatment other than PF, the developed regions will still repel ink, but the run length may be shorter than that of a plate made with a PF-treated substrate. If a PF-treated plate is rinsed with water instead of being gummed as described herein, the developed hydrophilic regions may not be sufficiently ink-repelling and instead attract ink, leading to a “toned” background with excessive ink stains on the printed sheet.

### EXAMPLES

### Example A

### Formulation for 5 Nax220-0.75 phenoxy-phos/citrate Developer Composition

A 5-gallon polyethylene container was charged with 15883.42 g of deionized water, and an overhead stirrer was set up over the container with a 2″ turboprop stirrer inside the tank. The tank was then agitated at 600 rpm. 221.88 g of Na₂HPO₄ and 18.76 g of citric acid were added to the container and allowed to stir 2 hours to mix. 1727.44 g of NAXAN 220 alkylnaphthalene sulfonate surfactant solution (52.1% total solids, Nease Chemical Co.) were added to the stirring buffer solution, followed by 135 g of phenoxyethanol and 13.5 g SURFYNOL DF-62 Defoamer (Air Products), and followed by at least 2 hours additional stirring. The pH of the resulting gum solution was 7.4.

### Example B

An NP-1 plate (also known as AQUATHERM SP from MYLAN printing media) was imaged at 12 watts laser power, 175 rpm drum speed on a Presstek COMPASS 8030 plate-setter (Presstek, Hudson, NH). The plate was then developed in a Presstek ANTHEM Water Wash processor using 5Nax220-0.75 phenoxy-phos/citrate developer composition in the developer stage and water in the rinse stage. The plate was subsequently processed through the rinse and gum sections of a Presstek AEON plate processor to coat the plate with a thin layer of Presstek Aeon Finisher/Preserver (part number: 1A10251, pH=3.4 to 3.5). The Finisher/Preserver was allowed to dry in place. The plate was mounted on a Heidelberg GTO printing press and run with Titan Process Black ink (GraphLine Inc., Sunrise, Fla.), Anchor Emerald JRB fountain (Fujifilm, Allendale, N.J.; 3 oz/gallon) with ARS-SV alcohol substitute (Fujifilm; 2 oz/gallon), and uncoated paper (Williamburg Plus 60 lb white). The plate rolled up within 25 impressions and was run to 200 impressions with good image quality and ink/water balance.

### Example C

Two NP-1 plates were imaged in a Kodak TRENDSETTER 400 plate-setter (Eastman Kodak, Rochester, N.Y.) operating at 200 rpm drum speed: one plate was imaged at 12 watts laser power, and the other was imaged at 16 watts. Both plates were developed in the ANTHEM Water Wash processor with 5Nax220-0.75 phenoxy-phosphate/citrate as in the previous example, and were gummed with AEON Finisher/Preserver. Both plates were run on the GTO press to 200 impressions under conditions described above, and both plates printed well with good image quality.

### Example D

An NP-1 plate was imaged on the COMPASS 8030 plate-setter at 16 watts laser power and 200 rpm drum speed with a 200 lpi image. It was processed and gummed as above. This plate was run on a Sakurai Oliver 72 press using an aggressive ink blend, Prisco 2451 fountain solution (Printers' Service, Hingham, MA; 3 oz/gallon) with ALKALESS 6000 alcohol substitute (Printers' Service; 2 oz/gallon), and uncoated printing stock as described above. The plate was run to 40,000 impressions with good image quality and ink-water balance.

### Example E

Two NP-1 plates were imaged on the COMPASS 8030 plate-setter, both at 200 rpm drum speed, with one plate exposed at 12 watts laser power and one at 16 watts using a 200 lpi image target. The plates were processed and gummed as above. The plates were then run on a Komori LITHRONE 28 press using Flint K+E Novastar F4 ink (Flint Group, Cleveland, Ohio), Prisco 3541 fountain solution (3 oz/gallon), ALKALESS 3000 alcohol substitute (Printers' Service; 2.5 oz/gallon) and NewPage 80 lb C1S label stock. Both plates had short make-ready time, rolling up to density in less than 25 sheets. The plate imaged at 12 watts ran with 2% dots and good mid-tones to 20,000 impressions. The plate imaged at 16 watts ran with good highlights to 30,000 impressions. Both plates ran without delta tracking scratches up to 50,000 impressions.

### Example F

An NP-1 plate is imaged at 12 watts laser power, 175 rpm drum speed on a COMPASS 8030 plate-setter. The plate is developed in an ANTHEM Water Washer using 5Nax220-0.75 phenoxy-phos/citrate developer composition in the developer stage and water in the rinse stage. The plate is subsequently processed through the rinse and gum sections of an AEON plate processor to coat the plate with a thin layer of Kodak plate finisher 850S (pH=2.1). The finisher is allowed to dry in place. The plate is mounted on a GTO printing press and run with Titan Process Black ink, Anchor Emerald JRB fountain (3 oz/gallon) with ARS-SV alcohol substitute (2 oz/gallon), and uncoated paper (Williamburg Plus 60 lb white). It is expected the plate will roll up within 25 impressions and will run to at least 200 impressions with good image quality.

### Example G

Example F is repeated except that the Kodak Plate Finisher 850S is replaced with Process Solutions Subtractive Finisher (Process Solutions Inc., East Longmeadow, Mass., pH=5.0). It is expected the plate will roll up within 25 impressions and will run to at least 200 impressions with good image quality.

### Example H

Example F is repeated except that the Kodak Plate Finisher 850S is replaced with Newsfin RC794 (Agfa Corporation, Ridgefield Park, N.J., pH =4.9). It is expected the plate will roll up within 25 impressions and will run to at least 200 impressions with good image quality.

### Example I

Example F is repeated except that the Kodak Plate Finisher 850S is replaced with General Machine finisher-gum RC795 (Agfa Corporation, pH=2.9). It is expected the plate will roll up within 25 impressions and will run to at least 200 impressions with good image quality.

### Example J

Example F is repeated except that the Kodak Plate Finisher 850S is replaced with Creo Thermal Storage Gum TSG-1 (Eastman Kodak, pH=2.2). It is expected the plate will roll up within 25 impressions and will run to at least 200 impressions with good image quality.

Although the present invention has been described with reference to specific details, it is not intended that such details should be regarded as limitations upon the scope of the invention, except as and to the extent that they are included in the accompanying claims.

What is claimed is:

1. A method of developing a printing member having a negative-working photopolymer imaging layer on an anodized aluminum substrate and which has been subjected to (i) a post-anodic sealing treatment of the substrate comprising exposure to an inorganic phosphate and an inorganic fluoride, and (ii) imagewise exposure of the printing member to actinic imaging radiation, the method comprising the steps of:
removing unimaged portions of the photopolymer by applying to the printing member a developer composition comprising water, a surfactant, and a polycarboxylic acid; and
protecting the printing member by applying thereto a finisher gum solution having a composition different from the developer composition.

2. The method of claim 1 wherein the developer has a pH in the range of 7 to 8.5 and the finisher gum solution has a pH in the range of 2 to 8.5.

3. The method of claim 1 wherein the finisher gum solution comprises water, surfactant and a polycarboxylic acid.

4. The method of claim 1 wherein the finisher gum solution comprises a hydrophilic polymer.

5. The method of claim 1 wherein the developer composition further comprises an organic, water-miscible cosolvent.

6. The method of claim 5 wherein the cosolvent is present at a level no greater than 5%.

7. The method of claim 5 wherein the cosolvent is at least one of benzyl alcohol, phenoxyethanol or propylene carbonate.

8. The method of claim 1 further comprising the step of passing the printing member through a squeeze roller before the finisher gum solution is applied.

9. The method of claim 1 wherein the finisher gum solution after drying has a deposited weight between 0.1 g/m² and 0.5 g/m².

10. The method of claim 1 wherein the polycarboxylic acid is citric acid.

11. The method of claim 3 wherein the polycarboxylic acid of the finisher gum solution is citric acid.

12. The method of claim 1 wherein the polycarboxylic acid constitutes between between 0.05 and 1% of the composition by weight.
